(19) United States
(12) Patent Application Publication
(10) Pub. No.: US 2025/0385212 A1
(43) Pub. Date: Dec. 18, 2025

(54) SEMICONDUCTOR PACKAGE AND METHOD OF MANUFACTURING THE SAME

(71) Applicant: Samsung Electronics Co., Ltd., Suwon-si (KR)

(72) Inventor: Boseok KWON, Suwon-si (KR)

(73) Assignee: Samsung Electronics Co., Ltd., Suwon-si (KR)

(21) Appl. No.: 19/020,038

(22) Filed: Jan. 14, 2025

(30) Foreign Application Priority Data
Jun. 17, 2024 (KR) 10-2024-0078527

(51) Int. Cl. H01L 23/00; H01L 23/544

(52) U.S. Cl. CPC H01L 24/29; H01L 23/544; H01L 24/30; H01L 24/32; H01L 24/83; H01L 2223/54426; H01L 2224/26165; H01L 2224/29035; H01L 2224/3003; H01L 2224/30051; H01L 2224/30179; H01L 2224/30515; H01L 2224/32111; H01L 2224/32225; H01L 2224/8314; H01L 2224/83143; H01L 2224/83193

(57) ABSTRACT

A semiconductor package may be provided. The semiconductor package may include a package substrate, a semiconductor chip on the package substrate, a solder resist pattern disposed between the package substrate and the semiconductor chip, the solder resist pattern having an opening region, an alignment mark disposed on the package substrate, the alignment mark in the opening region, and a solder paste pattern on a side surface of the alignment mark adjacent to the semiconductor chip, wherein the solder paste pattern is disposed between the semiconductor chip and the package substrate.

### CROSS-REFERENCE TO RELATED APPLICATIONS

This U.S. non-provisional patent application claims priority under 35 U.S.C. § 119 to Korean Patent Application No. 10-2024-0078527 filed on Jun. 17, 2024, in the Korean Intellectual Property Office, the entire contents of which are hereby incorporated by reference.

### BACKGROUND OF THE INVENTION

The inventive concepts relate to a semiconductor package and a method of manufacturing the same, and more specifically, relates to a semiconductor package with improved electrical characteristics and a method of manufacturing the same.

In manufacturing a semiconductor package, an alignment mark is formed on a printed circuit board to mount semiconductor chips in an accurate position on the printed circuit board. Methods for forming an alignment mark on the printed circuit board include a method of etching and partially removing solder resist on a surface of the printed circuit board, and a method of forming a metal alignment mark on a solder resist. The alignment mark may be used in a process of attaching various chips on the printed circuit board, and/or may be used to check and inspect whether the chips are attached in the correct position after attachment.

### SUMMARY

An object of the inventive concepts is to provide a semiconductor package with improved electrical characteristics.

An object of the inventive concepts is to provide a method of manufacturing a semiconductor package with improved electrical characteristics.

The problem to be solved by the inventive concepts is not limited to the problems mentioned above, and other problems not mentioned will be clearly understood by those skilled in the art from the description below.

A semiconductor package according to some embodiments of the inventive concepts may include a package substrate, a semiconductor chip on the package substrate, a solder resist pattern between the package substrate and the semiconductor chip, the solder resist pattern defining an opening region, an alignment mark disposed on the package substrate, the alignment mark in the opening region, and a solder paste pattern between the semiconductor chip and the package substrate and on a side surface of the alignment mark, the side surface adjacent to the semiconductor chip.

A semiconductor package according to some embodiments of the inventive concepts may include a package substrate, a first semiconductor chip on the package substrate, a plurality of second semiconductor chips stacked on the first semiconductor chip, a solder resist pattern between the package substrate and the first semiconductor chip, the solder resist pattern defining an opening region adjacent to the first semiconductor chip, an adhesive layer between the first semiconductor chip and the solder resist pattern, an alignment mark in the opening region, and a solder paste pattern between the alignment mark and the solder resist pattern in the opening region such that at least a portion of the solder paste pattern vertically overlaps the first semiconductor chip.

A method of manufacturing a semiconductor package according to some embodiments of the inventive concepts may include forming a solder resist pattern on a base layer such that the solder resist pattern defines an opening region and includes an alignment mark in the opening, depositing a first solder paste in the opening region, forming an adhesive layer and a second solder paste on a lower surface of the semiconductor chip, arranging the semiconductor chip on the base layer, and mounting the semiconductor chip on the base layer, wherein the mounting of the semiconductor chip includes forming a solder paste pattern by combining the first solder paste and the second solder paste to.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view for explaining a semiconductor package according to at least one embodiment of the inventive concepts.

FIG. 2 is a view for explaining a semiconductor package according to at least one embodiment of the inventive concepts, and is a cross-sectional view taken along line A-A′ of FIG. 1.

FIG. 3 is an enlarged view of region ‘P1’ of FIG. 2.

FIG. 4 and FIG. 5 are plan views for explaining a semiconductor package according to some embodiments of the inventive concepts.

FIG. 6 is a plan view for explaining a semiconductor package according to at least one embodiment of the inventive concepts.

FIG. 7 is a view for explaining a semiconductor package according to at least one embodiment of the inventive concepts, and is a cross-sectional view taken along line B-B′ of FIG. 6.

FIG. 8 to FIG. 16 are views for explaining a method of manufacturing a semiconductor package according to at least one embodiment of the inventive concepts.

### DETAILED DESCRIPTION

Hereinafter, embodiments of the inventive concepts will be described with reference to the attached drawings. Throughout the specification, the same reference numerals may refer to the same components, and therefore repeat descriptions thereof will be omitted. Some sizes of components in the drawings may be exaggerated for convenience of explanation. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will also be understood that such spatially relative terms, such as “above,” “top,” “vertical,” “lateral,” etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

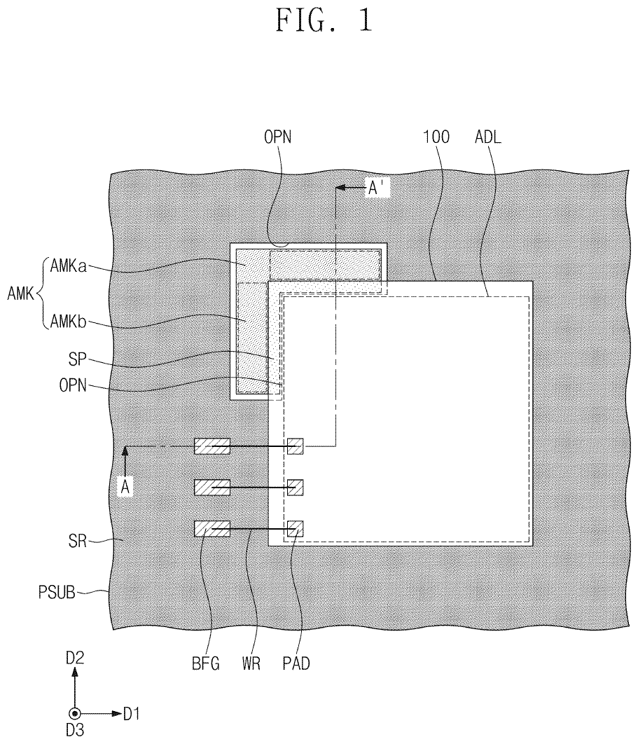

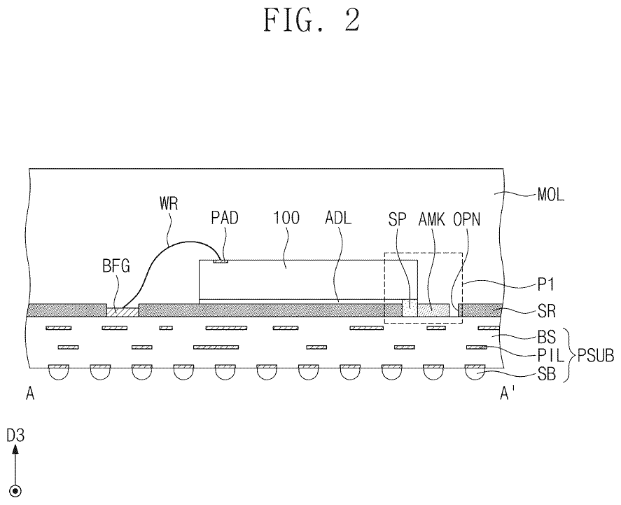

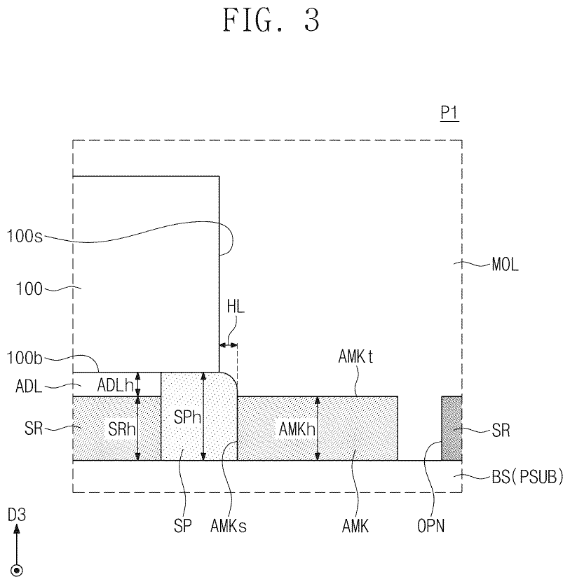

FIG. 1 is a plan view for explaining a semiconductor package according to at least one embodiment of the inventive concepts. FIG. 2 is a view for explaining a semiconductor package according to at least one embodiment of the inventive concepts, and is a cross-sectional view taken along line A-A′ of FIG. 1. FIG. 3 is an enlarged view of region ‘P1’ of FIG. 2.

Referring to FIGS. 1 and 2, a semiconductor package according to at least one embodiment of the inventive concepts may include a package substrate PSUB, a semiconductor chip 100 on the package substrate PSUB, and a molding layer MOL covering the package substrate PSUB and the semiconductor chip 100. For example, the semiconductor chip 100 may be mounted on the package substrate PSUB.

The package substrate PSUB may include a base layer BS, substrate wirings PIL provided in the base layer BS, and terminals SB provided on a lower surface of the base layer BS. For example, the package substrate PSUB may be and/or include a printed circuit board (PCB).

The base layer BS may be formed of an organic substrate material, for example, at least one material selected from phenol resin, epoxy resin, polyimide, and/or the like. The base layer BS may be composed of a single layer or a multilayer layer laminated in a vertical direction (e.g., a third direction D3). For example, the base layer BS may include at least one material selected from Flame Retardant 4 (FR4), tetrafunctional epoxy, polyphenylene ether, epoxy/polyphenylene oxide, Bismaleimide triazine (BT), Thermount, cyanate ester, polyimide, liquid crystal polymer, and prepreg. In the present specification, the prepreg may be formed by impregnating glass fiber with an epoxy resin and may have, e.g., a sheet shape.

The substrate wirings PIL may be disposed in the base layer BS. The substrate wirings PIL may have a form extending in a horizontal direction (e.g., a first direction D1 or a second direction D2). The substrate wirings PIL may be spaced apart from each other in a vertical direction and/or a horizontal direction. For example, the substrate wirings PIL may include layers at different vertical heights, with each of the layers including a plurality of wiring spaced apart from each other in the horizontal directions. Additionally, the substrate wirings PIL may include vias electrically connecting the layers. For example, vias may be provided between vertically adjacent substrate wirings PIL, and the vias may electrically connect the substrate wirings PIL. For example, the substrate wirings PIL may include a metal and/or metallically conductive material such as copper (Cu), silver (Ag), aluminum (Al), nickel (Ni), and/or the like.

The terminals SB may be disposed on a lower surface of the base layer BS. Each of the terminals SB may be connected to the lowest substrate wirings PIL among the substrate wirings PIL. The terminals SB may include signal terminals and power/ground terminals. The terminals SB may be electrically connected to connection pads BFG on the package substrate PSUB, which will be described below, through the substrate wirings PIL. In addition, the semiconductor package may be configured to be electrically connected to an external device through the terminals SB. As a result, an external electrical signal and/or a power/ground voltage may be provided to the semiconductor package through the terminals SB. For example, the terminals SB may include tin (Sn), silver (Ag), copper (Cu), zinc (Zn), lead (Pb), and/or alloys thereof.

Connection pads BFG may be provided on the package substrate PSUB. In at least some embodiments, the connection pads BFG may be provided on a surface of the package substrate PSUB opposite to the surface on which the terminal SB are provided. For example, the connection pads BFG may be in contact with an upper surface of the base layer BS of the package substrate PSUB. The connection pads BFG may include signal connection pads and/or power/ground connection pads. The connection pads BFG may be spaced apart from each other and electrically insulated from each other. The connection pads BFG may be disposed on one side of the semiconductor chip 100. The connection pads BFG may be spaced apart from the semiconductor chip 100 horizontally and may not vertically overlap. The connection pads BFG may be electrically connected to the substrate wirings PIL of the package substrate PSUB. For example, the connection pads BFG may include a metal material such as aluminum (Al), copper (Cu), silver (Ag), nickel (Ni), and/or the like.

A solder resist pattern SR may be provided on the package substrate PSUB. The solder resist pattern SR may cover a portion of the upper surface of a base layer BS. The solder resist pattern SR may expose the connection pads BFG. As a result, the connection pads BFG may be connected to bonding wires WR described below. For example, the solder resist pattern SR may include at least one of a thermally curable solder resist, a UV-curable solder resist, a composite-curable solder resist, and/or a photosensitive material. The photosensitive material may include a polyurethane resin, an inorganic filler, a polymerizable compound, a photopolymerization initiator, and/or the like. Alternatively, the solder resist pattern SR may include an insulating material such as epoxy resin, polyimide resin, BT resin, and Terlon resin.

The solder resist pattern SR may have and/or define an opening region OPN adjacent to the semiconductor chip 100. When viewed in a plan view, the opening region OPN may extend from a corner of the semiconductor chip 100 to the adjacent side surfaces of the semiconductor chip 100. For example, the opening region OPN may have a ‘L’-shape when viewed in a plan view. The opening region OPN may expose the upper surface of the base layer BS.

An alignment mark AMK may be provided in the opening region OPN of the solder resist pattern SR. The alignment mark AMK may be in contact with the upper surface of the base layer BS of the package substrate PSUB. The alignment mark AMK may be disposed in the opening region OPN, and may thereby be adjacent to the semiconductor chip 100. In at least some embodiments, the alignment mark AMK may include a metal material such as aluminum (Al), copper (Cu), tungsten (W), molybdenum (Mo), and cobalt (Co), or an insulating material such as an epoxy resin.

The alignment mark AMK may include a first portion AMKa and two second portions AMKb. When viewed in a plan view, the first portion AMKa of the alignment mark AMK may be disposed adjacent to the corner of the semiconductor chip 100. Each of the second portions AMKb may extend from the first portion AMKa. Each of the second portions AMKb may extend from the first portion AMKa to correspond with the side surfaces of the semiconductor chip 100 adjacent to the first portion AMKa. For example, one of the second portions AMKb may extend in the first direction D1, and the other of the second portions AMKb may extend in the second direction D2. When viewed in a plan view, the alignment mark AMK may have a shape similar to the opening region OPN. That is, the alignment mark AMK may have a ‘L’-shape when viewed in a plan view.

A solder paste pattern SP may be provided between the alignment mark AMK and the solder resist pattern SR. When viewed in a plan view, the solder paste pattern SP may have a shape similar to the alignment mark AMK and may overlap a portion of the semiconductor chip 100. The solder paste pattern SP may be disposed in the opening region OPN of the solder resist pattern SR and may fill a portion of the opening region OPN. In addition, the solder paste pattern SP may be disposed between the base layer BS of the package substrate PSUB and the semiconductor chip 100. In at least some embodiments, the solder paste pattern SP may include tin (Sn), silver (Ag), copper (Cu), zinc (Zn), lead (Pb), and/or their alloys in powder form, polymers such as ethyl cellulose and epoxy, and solvents such as acids and acetate series.

The semiconductor chip 100 may be disposed on the package substrate PSUB. A portion of the solder resist pattern SR and the solder paste pattern SP may be disposed between the semiconductor chip 100 and the package substrate PSUB. The semiconductor chip 100 may include integrated circuits therein. The integrated circuits inside the semiconductor chip 100 may include, e.g., volatile and/or nonvolatile memory circuits. For example, the semiconductor chip 100 may include a dynamic random access memory (DRAM). The semiconductor chip 100 may include pads PAD on an upper surface thereof. The pads PAD may be electrically connected to the integrated circuits inside the semiconductor chip 100. The pads PAD may be spaced apart from each other and electrically insulated from each other. Each of the pads PAD may be connected to the connection pads BFG, e.g., through the bonding wires WR. As a result, pads PAD of the semiconductor chip 100 may be electrically connected to the package substrate PSUB. For example, the bonding wires WR may include a metal and/or metallically conductive material such as gold (Au) or aluminum (Al).

An adhesive layer ADL may be provided between the semiconductor chip 100 and the solder resist pattern SR. The adhesive layer ADL may be in contact with each of the semiconductor chip 100 and the solder resist pattern SR such that the adhesive layer ADL attaches the solder resist pattern SR to the semiconductor chip 100. For example, the adhesive layer ADL may cover about 80% to about 90% of a lower surface of the semiconductor chip 100. In at least some embodiments, the adhesive layer ADL may include a curable adhesive, such as a resin, epoxy, and/or the like. The planar area of the adhesive layer ADL may be larger than the planar area of the solder paste.

Referring to FIG. 3, the alignment mark AMK may be disposed in the opening region OPN of the solder resist pattern SR and may be spaced apart from the solder resist pattern SR. That is, in at least some embodiments, the alignment mark AMK may not be in contact with the solder resist pattern SR. Each of the solder resist pattern SR and the alignment mark AMK may have a thickness in a vertical direction (e.g., the third direction D3). In at least some embodiments, the vertical thickness SRh of the solder resist pattern SR and a vertical thickness AMKh of the alignment mark AMK may be substantially the same as (and/or substantially similar to) each other. For example, each of the vertical thickness SRh of the solder resist pattern SR and the vertical thickness AMKh of the alignment mark AMK may be about 50 micrometers (μm).

The solder paste pattern SP may be disposed on the side AMKs of the alignment mark AMK adjacent to the semiconductor chip 100. The solder paste pattern SP may be in contact with and between the alignment mark AMK and the solder resist pattern SR. In addition, the solder paste pattern SP may be in contact with a side surface of the adhesive layer ADL. In at least some embodiments, the solder paste pattern SP may be in contact with the upper surface of the base layer BS of the package substrate PSUB and a lower surface 100b of the semiconductor chip 100. At least a portion of the solder paste pattern SP may vertically overlap the semiconductor chip 100. For example, the solder paste pattern SP may partially and/or completely fill a portion of the opening region OPN that vertically overlaps with the semiconductor chip 100.

Each of the solder paste pattern SP and the adhesive layer ADL may have a thickness in the vertical direction. A vertical thickness SPh of the solder paste pattern SP may be greater than the vertical thickness SRh of the solder resist pattern SR. For example, the vertical thickness SPh of the solder paste pattern SP may be substantially equal to the sum of the vertical thickness SRh of the solder resist pattern SR and a vertical thickness ADLh of the adhesive layer ADL. The vertical thickness ADLh of the adhesive layer ADL may be about 10 μm.

The semiconductor chip 100 may be disposed on the adhesive layer ADL and the solder paste pattern SP. A portion of the lower surface 100b of the semiconductor chip 100 may be in contact with the solder paste pattern SP, and the remainder of the lower surface 100b of the semiconductor chip 100 may be in contact with the adhesive layer ADL. The semiconductor chip 100 may be spaced apart in a vertical direction from the package substrate PSUB and the solder resist pattern SR due to the adhesive layer ADL and the solder paste pattern SP. That is, the lower surface 100b of the semiconductor chip 100 may be higher than an upper surface of the solder resist pattern SR. In addition, the lower surface 100b of the semiconductor chip 100 may be higher than an upper surface AMKt of the alignment mark AMK.

According to at least one embodiment, one side 100s of the semiconductor chip 100 adjacent to (or facing) the alignment mark AMK and the one side AMKs of the alignment mark AMK adjacent to (or facing) the semiconductor chip 100 may be horizontally spaced apart from each other. When viewed in a plan view and/or a cross-sectional view, the alignment mark AMK and the semiconductor chip 100 may not overlap. In these cases, a horizontal distance HL between the one side 100s of the semiconductor chip 100 and the one side AMKs of the alignment mark AMK may be about 30 μm or less.

Alternatively, according to at least one embodiment, the one side 100s of the semiconductor chip 100 adjacent to the alignment mark AMK and the one side AMKs of the alignment mark AMK adjacent to the semiconductor chip 100 may not be horizontally spaced apart from each other. In these cases, the one side 100s of the semiconductor chip 100 and the one side AMKs of the alignment mark AMK may be vertically aligned. That is, the horizontal distance HL between the one side 100s of the semiconductor chip 100 and the one side AMKs of the alignment mark AMK may substantially not exist.

Referring again to FIGS. 1 and 2, the molding layer MOL may be disposed on a package substrate PSUB. The molding layer MOL may cover the solder resist pattern SR, the semiconductor chip 100, the alignment mark AMK, and the bonding wires WR. For example, the molding layer MOL may include an insulating polymer such as an epoxy-based molding compound.

The semiconductor package according to at least one embodiment of the inventive concepts may include the solder paste pattern SP disposed between the alignment mark AMK and the solder resist pattern SR and on the lower surface of a semiconductor chip 100. In a method of manufacturing a semiconductor package described below, two solder pastes are combined to form one solder paste pattern SP. In these cases, the semiconductor chip 100 may be disposed adjacent to the alignment mark AMK due to an intermolecular attraction between the solder pastes. For example, the distance between the one side 100s of the semiconductor chip 100 and the one side AMKs of the alignment mark AMK may be about 30 μm or less. In other words, due to the intermolecular attraction, the semiconductor chip 100 may be self-aligned and mounted on the package substrate PSUB. As a result, the bonding wires WR may be accurately connected to the pads PAD of the semiconductor chip 100. Therefore, defects in the semiconductor package may be minimized or prevented, and electrical characteristics of the semiconductor package may be improved.

In addition, the planar area of the solder paste pattern SP may be smaller than the planar area of the adhesive layer ADL. For example, the adhesive layer ADL may have a relatively larger planar area than that of the solder paste pattern SP. As a result, the potential for the semiconductor chip 100 to be peeled off from the package substrate PSUB (due to bleeding phenomenon of the solder paste pattern SP) may be reduced and/or minimized. Therefore, durability of the semiconductor package may also be improved.

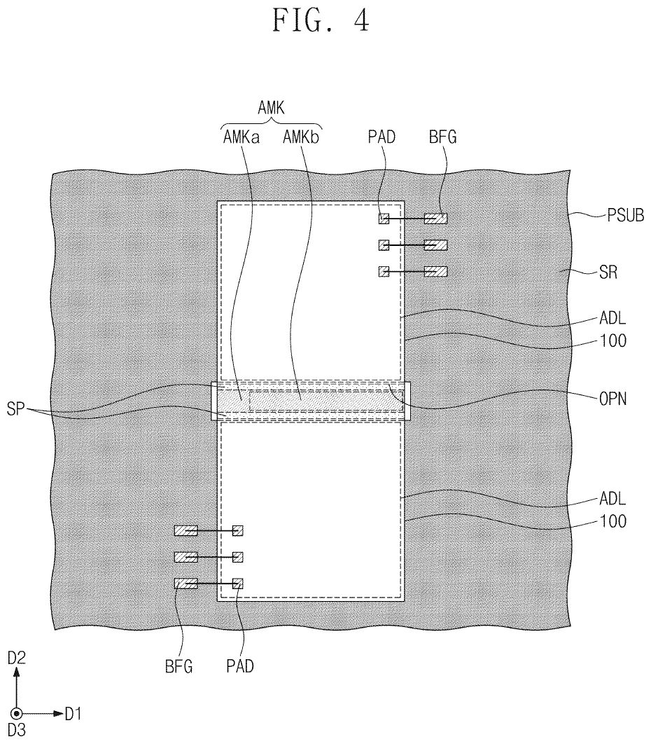

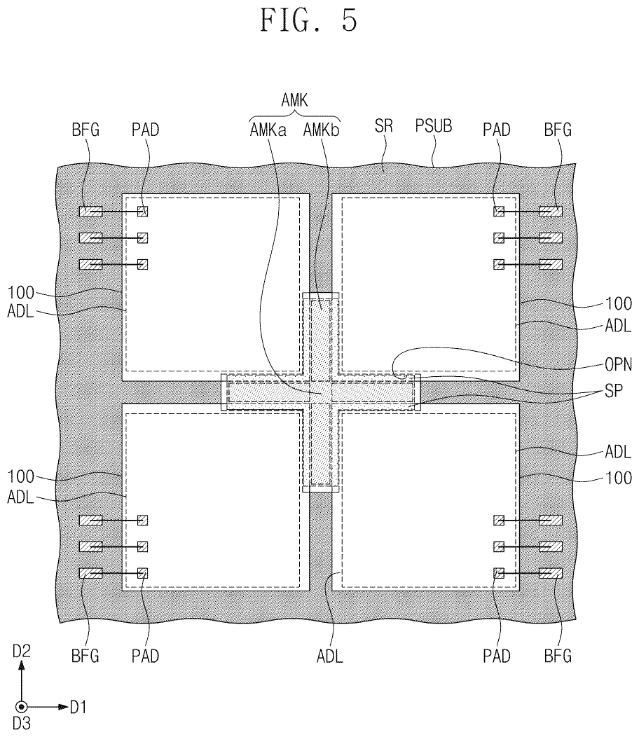

FIG. 4 and FIG. 5 are plan views for explaining a semiconductor package according to embodiments of the inventive concepts.

Referring to FIG. 4, two semiconductor chips 100 may be provided. The semiconductor chips 100 may be spaced apart from each other. The semiconductor chips 100 may be spaced apart from each other in the second direction D2, but the examples are not limited thereto. For example, the semiconductor chips 100 may be spaced apart from each other in the first direction D1. Each of the semiconductor chips 100 may otherwise be substantially the same as (and/or substantially similar to) described with reference to FIGS. 1 to 3.

A solder resist pattern SR may have an opening region OPN adjacent to the semiconductor chips 100. The opening region OPN may be disposed between the semiconductor chips 100. The opening region OPN may extend in the first direction D1 between the semiconductor chips 100. For example, the opening region OPN may have a line shape or a bar shape when viewed in a plan view.

An alignment mark AMK may be provided in the opening region OPN of the solder resist pattern SR. The alignment mark AMK may include a first portion AMKa and a second portion AMKb extending from the first portion AMKa. For example, the first portion AMKa may be disposed at one end of the opening region OPN. The second portion AMKb may extend from the first portion AMKa toward the other end of the opening region OPN. The alignment mark AMK may have a planar shape substantially similar to that of the opening region OPN. That is, the alignment mark AMK may have a line or a bar shape when viewed in a plan view.

In the opening region OPN of the solder resist pattern SR, solder paste patterns SP may be provided on sides of the alignment mark AMK. The solder paste patterns SP may be spaced apart from each other in the second direction D2 with respect to the alignment mark AMK. Each of the solder paste patterns SP may have a shape extending in the first direction D1. Each of the solder paste patterns SP may cover a portion of a lower surface of the semiconductor chips 100 as described with reference to FIG. 3. In addition, at least a portion of the solder paste patterns SP may be vertically overlapped with adjacent semiconductor chips 100.

Each of adhesive layers ADL may cover a remainder (and/or the remainder) of the lower surface of the semiconductor chips 100 that is not covered by the solder paste patterns SP. For example, the adhesive layers ADL may completely cover the remainder of the lower surface of the semiconductor chips 100 and/or may cover a majority of the remainder of the lower surface of the semiconductor chips 100. The planar area of each of the adhesive layers ADL may be larger than the planar area of each of the solder paste patterns SP.

Referring to FIG. 5, four semiconductor chips 100 may be provided. The semiconductor chips 100 may be spaced apart from each other. The semiconductor chips 100 may be spaced apart from each other in a horizontal direction (e.g., the first direction D1 and/or the second direction D2). When viewed in a plan view, the semiconductor chips 100 may be arranged two-dimensionally. Each of the semiconductor chips 100 may otherwise be substantially the same as (and/or substantially similar to) described with reference to FIGS. 1 to 3.

The solder resist pattern SR may have an opening region OPN adjacent to the semiconductor chips 100. The opening region OPN may be disposed between the semiconductor chips 100. The opening region OPN may extend in the first direction D1 and the second direction D2 between the semiconductor chips 100. For example, the opening region OPN may be ‘+’-shaped when viewed in a plan view.

The alignment mark AMK may be provided in the opening region OPN of the solder resist pattern SR. The alignment mark AMK may include a first portion AMKa and four second portions AMKb extending from the first portion AMKa. For example, the first portion AMKa may be disposed at a center of the opening region OPN. Each of the second portions AMKb may extend from the first portion AMKa to one end of the opening region OPN. Each of the second portions AMKb may be disposed between adjacent semiconductor chips 100. The alignment mark AMK may have a planar shape substantially similar to that of the opening region OPN. That is, the alignment mark AMK may be ‘+’-shaped when viewed in a plan view.

In the opening region OPN of the solder resist pattern SR, solder paste patterns SP may be provided on side surfaces of the alignment mark AMK. The solder paste patterns SP may be spaced apart from each other in the first direction D1 and the second direction D2 with respect to the alignment mark AMK. For example, each of the solder paste patterns SP may have a ‘L’-shape when viewed in a plan view. Each of the solder paste patterns SP may cover a portion of the lower surface of the semiconductor chips 100 as described with reference to FIG. 3. In addition, at least a portion of the solder paste patterns SP may vertically overlap the adjacent semiconductor chips 100.

The adhesive layers ADL may cover the remainder of the lower surface of the semiconductor chips 100 that is not covered by the solder paste patterns SP. The planar area of each of the adhesive layers ADL may be larger than the planar area of each of the solder paste patterns SP.

Referring again to FIGS. 1, 4, and 5, the semiconductor chip 100 may include a plurality of semiconductor chips 100. The alignment mark AMK may include a first portion AMKa and a second portion AMKb extending from the first portion AMKa. In at least some embodiments, the second portion AMKb may include a plurality of second portions AMKb. Each of the plurality of second portions AMKb may be disposed between adjacent plurality of semiconductor chips 100. As a result, at least one semiconductor chip 100 may be mounted on the package substrate PSUB while being self-aligned with one alignment mark AMK.

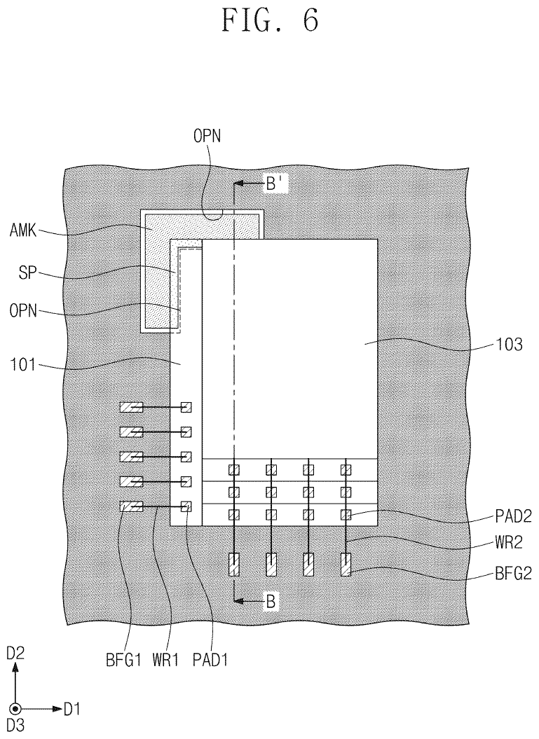

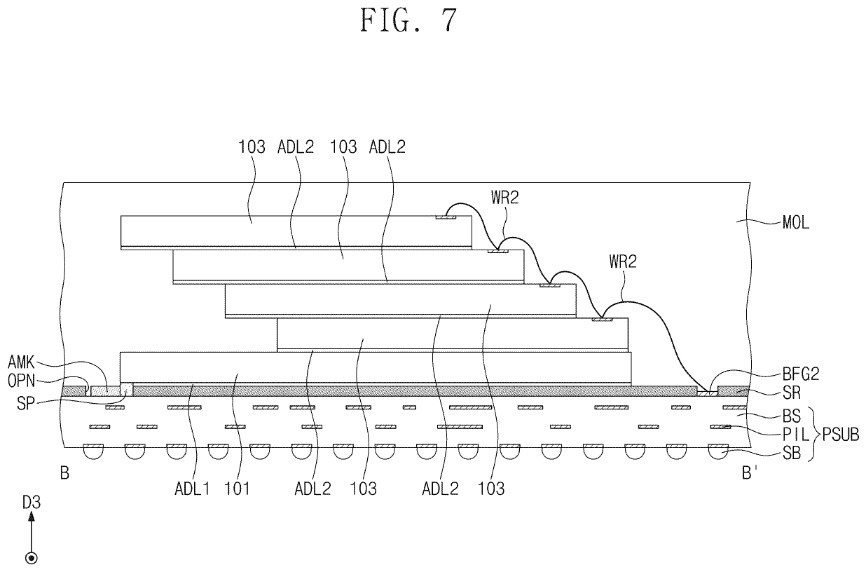

FIG. 6 is a plan view for explaining a semiconductor package according to at least one embodiment of the inventive concepts. FIG. 7 is a view for explaining a semiconductor package according to at least one embodiment of the inventive concepts, and is a cross-sectional view taken along line B-B′ of FIG. 6.

Referring to FIGS. 6 and 7, a semiconductor package may include a package substrate PSUB, a first semiconductor chip 101 on the package substrate PSUB, a plurality of second semiconductor chips 103, and a molding layer MOL covering the first semiconductor chip 101 and the plurality of second semiconductor chips 103.

The package substrate PSUB may include a base layer BS, substrate wirings PIL provided in the base layer BS, and terminals SB provided on a lower surface of the base layer BS. For example, the package substrate PSUB may be substantially the same as (and/or substantially similar to) described with reference to FIGS. 1 and 2.

A solder resist pattern SR having an opening region OPN adjacent to a first semiconductor chip 101 on the package substrate PSUB, an alignment mark AMK in the opening region OPN, and a solder paste pattern SP disposed on a side of the alignment mark AMK in the opening region OPN and on a lower surface of the first semiconductor chip 101 may be provided. Each of the solder resist pattern SR, the alignment mark AMK, and the solder paste pattern SP may be substantially the same as (and/or substantially similar to) described with reference to FIGS. 1 to 3.

The first semiconductor chip 101 may be disposed on the package substrate PSUB. The first semiconductor chip 101 may be disposed adjacent to the opening region OPN and the alignment mark AMK of the solder resist pattern SR. The first semiconductor chip 101 may be vertically overlapped with at least a portion of the solder paste pattern SP. The first semiconductor chip 101 may include first pads PAD1 on an upper surface thereof. The first pads PAD1 may be connected to first connection pads BFG1 on the package substrate PSUB through first bonding wires WR1. As a result, the first semiconductor chip 101 may be electrically connected to the package substrate PSUB. For example, the first semiconductor chip 101 may be substantially the same as (and/or substantially similar to) the semiconductor chip 100 described with reference to FIGS. 1 to 3.

A first adhesive layer ADL1 may be provided between the solder resist pattern SR and the first semiconductor chip 101. The first adhesive layer ADL1 may be in contact with an upper surface of the solder resist pattern SR and a lower surface of the first semiconductor chip 101 and may attach the solder resist pattern SR to the first semiconductor chip 101. The first adhesive layer ADL1 may be substantially the same as the adhesive layer ADL described with reference to FIGS. 1 to 3.

The plurality of second semiconductor chips 103 may be disposed on the first semiconductor chip 101. The plurality of second semiconductor chips 103 may be stacked in a vertical direction (e.g., the third direction D3). Ends of the plurality of second semiconductor chips 103 may not fully vertically overlap each other. For example, the plurality of second semiconductor chips 103 may be offset from each other. For example, the plurality of second semiconductor chips 103 may form a step structure.

Each of the second semiconductor chips 103 may include second pads PAD2 on an upper surface thereof. The second pads PAD2 may be connected to second connection pads BFG2 on the package substrate PSUB through second bonding wires WR2. As a result, the second semiconductor chips 103 may be electrically connected to the package substrate PSUB. Each of the second semiconductor chips 103 may include integrated circuits therein. In at least some embodiments, the integrated circuits inside the second semiconductor chips 103 may include memory circuits, such as nonvolatile memory circuits. For example, the second semiconductor chips 103 may include VNAND.

Second adhesive layers ADL2 may be provided between the first semiconductor chip 101 and the lowermost one of the plurality of second semiconductor chips 103 and between the plurality of second semiconductor chips 103. For example, the second adhesive layers ADL2 may be disposed on a lower surface of each of the plurality of second semiconductor chips 103. The second adhesive layers ADL2 may attach the plurality of second semiconductor chips 103 on the first semiconductor chip 101. The second adhesive layers ADL2 may include substantially the same material as the first adhesive layer ADL1.

A molding layer MOL may be disposed on the package substrate PSUB. The molding layer MOL may cover the solder resist pattern SR, the first semiconductor chip 101, the plurality of second semiconductor chips 103, the alignment mark AMK, the first bonding wires WR1, and the second bonding wires WR2. The molding layer MOL may have an upper surface higher than an upper surface of the uppermost one among the plurality of second semiconductor chips 103.

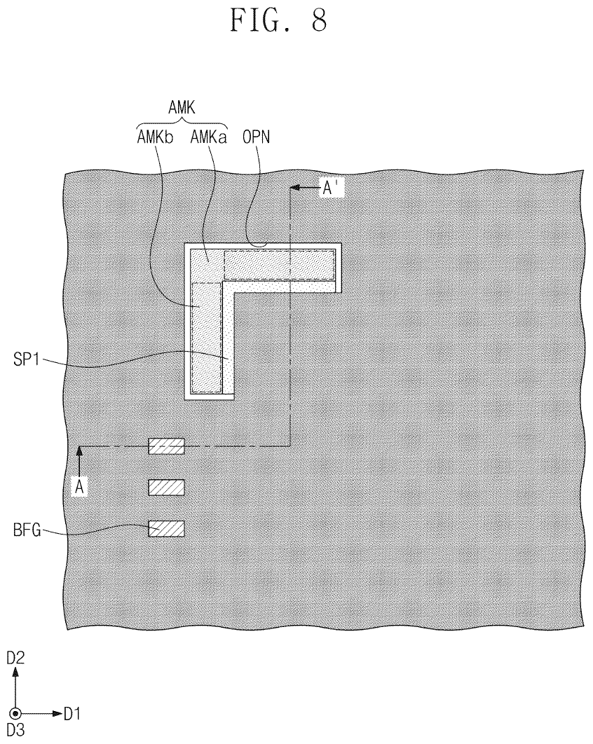

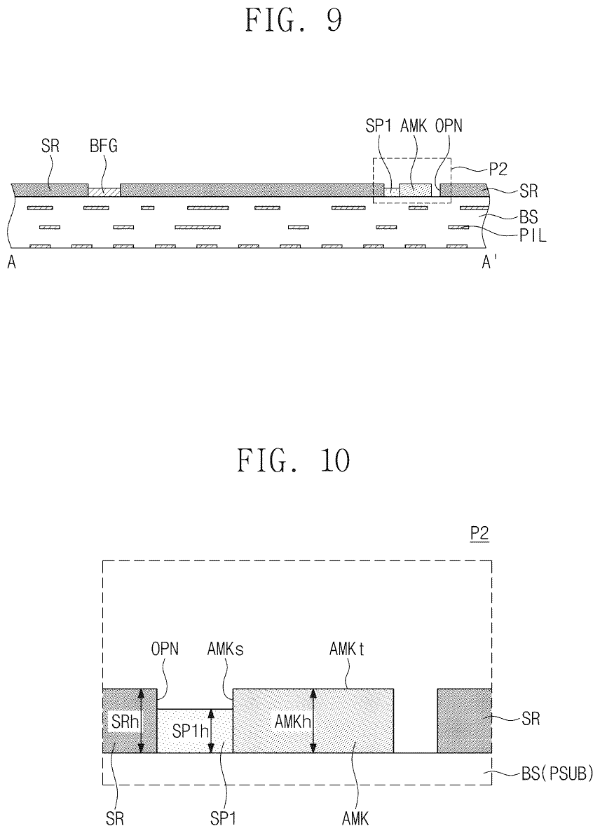

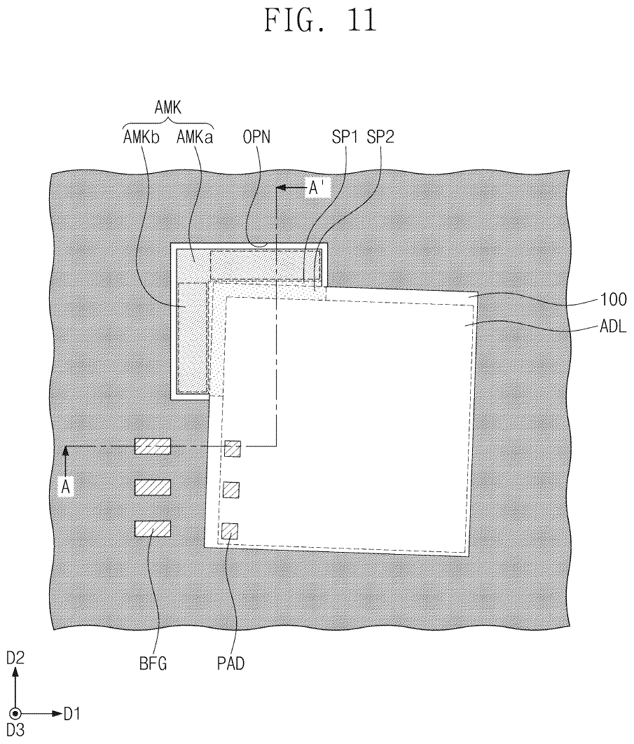

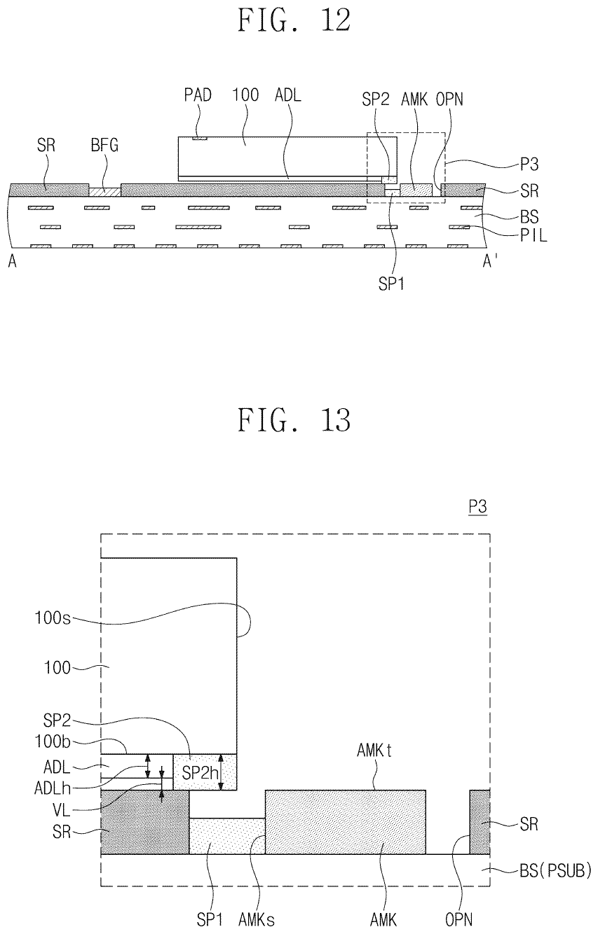

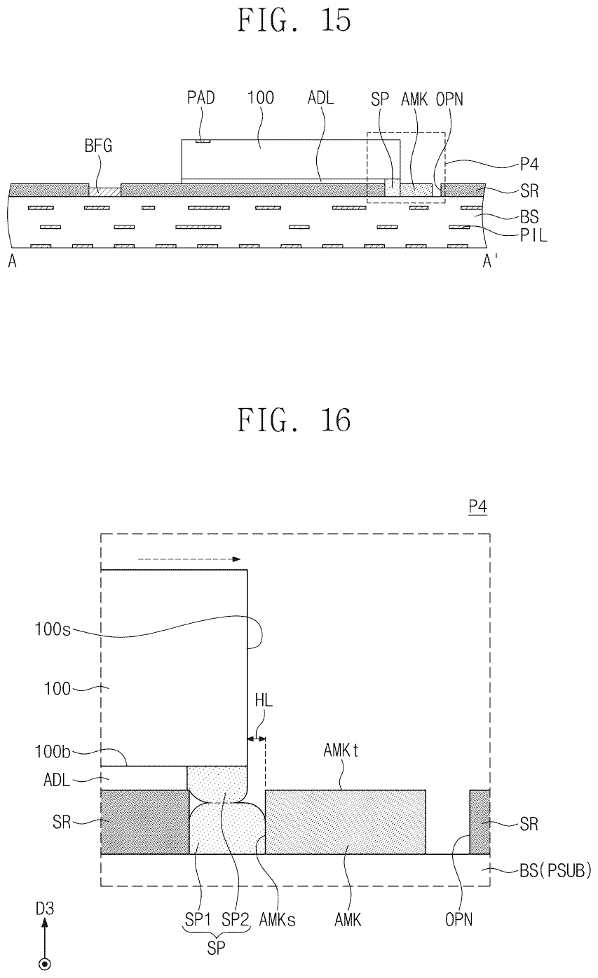

FIG. 8 to FIG. 16 are views for explaining a method of manufacturing a semiconductor package according to at least one embodiment of the inventive concepts. FIGS. 8, 11, and 14 are plan views of semiconductor packages according to some embodiments of the inventive concepts, FIGS. 9, 12, and 15 are cross-sectional views taken along lines A-A′ of FIGS. 8, 11, and 14, respectively, and FIGS. 10, 13, and 16 are enlarged views of region ‘P2’ of FIG. 9, P3 of FIG. 12, and region ‘P4’ of FIG. 15.

Referring to FIGS. 8, 9, and 10, a base layer BS including substrate wirings PIL therein may be provided. Connection pads BFG and alignment marks AMK may be formed on an upper surface of the base layer BS.

Forming the connection pads BFG may include forming a metal layer on an upper surface of the base layer BS and patterning the metal layer. The connection pads BFG may be spaced apart from each other in the second direction D2. The connection pads BFG may be electrically insulated from each other. The connection pads BFG may be electrically connected to the substrate wirings PIL in the base layer BS.

Forming the alignment mark AMK may include forming a first portion AMKa and two second portions AMKb extending from the first portion AMKa, respectively. The first portion AMKa and the second portions AMKb of the alignment mark AMK may be formed at one time through patterning. The alignment mark AMK may have a configuration indicating a region where a semiconductor chip 100 described below is placed. The alignment mark AMK may have a thickness AMKh in a vertical direction. For example, the alignment mark AMK may be formed simultaneously with the connection pads BFG, but is not limited thereto.

Thereafter, a solder resist pattern SR may be formed on the base layer BS. Forming the solder resist pattern SR may include forming a solder resist layer covering the upper surfaces of the base layer BS, the connection pads BFG, and the alignment mark AMK, removing a portion of the solder resist layer to expose the connection pads BFG, and removing a portion of the solder resist layer to form an opening region OPN. The opening region OPN may expose the alignment mark AMK. The alignment mark AMK may be disposed in the opening region OPN and may be spaced apart from the solder resist pattern SR.

The solder resist pattern SR may have a thickness in a vertical direction. A vertical thickness SRh of the solder resist pattern SR may be substantially the same as a vertical thickness AMKh of the alignment mark AMK.

A first solder paste SP1 may be formed in the opening region OPN. The first solder paste SP1 may fill a portion of the opening region OPN between the alignment mark AMK and the solder resist pattern SR. When viewed in a plan view, the first solder paste SP1 may have a ‘L’-shape. For example, the first solder paste SP1 may be formed by a process using an inkjet and/or a dispenser. The first solder paste SP1 may include at least one of tin (Sn), silver (Ag), copper (Cu), zinc (Zn), lead (Pb), and/or alloys thereof in powder form, a polymer such as ethyl cellulose or epoxy, and a solvent such as an acid or an acetate series.

The first solder paste SP1 may have a thickness SP1h in the vertical direction. The vertical thickness SP1h of the first solder paste SP1 may be smaller than the vertical thickness SRh of the solder resist pattern SR and/or the vertical thickness AMKh of the alignment mark AMK. For example, the vertical thickness SP1h of the first solder paste SP1 may be about 0.3 to about 0.7 times the vertical thickness SRh of the solder resist pattern SR. As a result, an upper surface of the first solder paste SP1 may be lower than an upper surface AMKt of the alignment mark AMK. In addition, a space may be formed on the first solder paste SP1 between the alignment mark AMK and the solder resist pattern SR.

Referring to FIGS. 11, 12, and 13, a semiconductor chip 100 may be placed on the base layer BS. Before the semiconductor chip 100 is placed on the base layer BS, an adhesive layer ADL and a second solder paste SP2 may be formed on a lower surface 100b of the semiconductor chip 100. The adhesive layer ADL and the second solder paste SP2 may be in contact with the lower surface 100b of the semiconductor chip 100. The second solder paste SP2 may cover a portion of the lower surface 100b of the semiconductor chip 100. The adhesive layer ADL does not overlap the second solder paste SP2 and may cover the remainder of the lower surface 100b of the semiconductor chip 100.

When viewed in a plan view, the second solder paste SP2 may be in a form that corresponds with the portion of the opening OPN including the first solder paste SP1 (e.g., that extends to a corner of the semiconductor chip 100 and side surfaces of the semiconductor chip 100 adjacent to the corner). For example, the second solder paste SP2 may have substantially the same shape as the first solder paste SP1. That is, the second solder paste SP2 may have a ‘L’-shape when viewed in a plan view. In addition, the second solder paste SP2 may be formed by substantially the same process as the first solder paste SP1, and the second solder paste SP2 may include substantially the same (and/or substantially similar) material as the first solder paste SP1.

The adhesive layer ADL may cover most of the lower surface 100b of the semiconductor chip 100. When viewed in a plan view, the area of the adhesive layer ADL may be larger than the area of the second solder paste SP2. For example, the planar area of the adhesive layer ADL may correspond to about 80% to about 90% of the lower surface 100b of the semiconductor chip 100. The adhesive layer ADL may be a die attach film (DAF).

The second solder paste SP2 and the adhesive layer ADL may each have a thickness in a vertical direction. The vertical thickness SP2h of the second solder paste SP2 may be greater than the vertical thickness ADLh of the adhesive layer ADL. For example, the vertical thickness ADLh of the adhesive layer ADL may be about 10 μm, and the vertical thickness SP2h of the second solder paste SP2 may be about 20 μm.

The semiconductor chip 100 may be disposed adjacent to the opening region OPN of the solder resist pattern SR and the alignment mark AMK. In detail, the semiconductor chip 100 may be arranged such that the second solder paste SP2 on the lower surface 100b of the semiconductor chip 100 and the first solder paste SP1 in the opening region OPN of the solder resist pattern SR overlap each other. Accordingly, the second solder paste SP2 may be disposed in the space on the first solder paste SP1, but is not limited thereto. The corner of the semiconductor chip 100 may be adjacent to the first portion AMKa of the alignment mark AMK.

The corner of the semiconductor chip 100 may be adjacent to the first portion AMKa of the alignment mark AMK. The side surfaces of the semiconductor chip 100 adjacent to the corner of the semiconductor chip 100 may be adjacent to the second portions AMKb of the alignment mark AMK. When viewed in a plan view, the first solder paste SP1 and the second solder paste SP2 may partially overlap. That is, the first solder paste SP1 and the second solder paste SP2 may vertically overlap, but the examples not limited thereto. For example, the first solder paste SP1 and the second solder paste SP2 may be spaced apart in a horizontal direction (e.g., in the first direction D1 and the second direction D2) and may not vertically overlap. One side 100s of the semiconductor chip 100 and one side AMKs of the alignment mark AMK may be adjacent to each other.

As the vertical thickness SP2h of the second solder paste SP2 is greater than the vertical thickness ADLh of the adhesive layer ADL, the adhesive layer ADL and the solder resist pattern SR may be spaced apart from each other. The second solder paste SP2 may support the semiconductor chip 100 on the solder resist pattern SR. As a result, the adhesive layer ADL may not come into contact with (and/or only partially contact) the solder resist pattern SR. A vertical distance VL between a lower surface of the adhesive layer ADL and an upper surface of the solder resist pattern SR may be about 10 μm. As a result, the adhesive layer ADL and the solder resist pattern SR may not be in contact with each other, and the semiconductor chip 100 may not be attached to the solder resist pattern SR. Therefore, the semiconductor chip 100 may be easily moved on the solder resist pattern SR. In other words, placing the semiconductor chip 100 on the base layer BS may include spacing the adhesive layer ADL on the lower surface 100b of the semiconductor chip 100 and the solder resist pattern SR apart from each other.

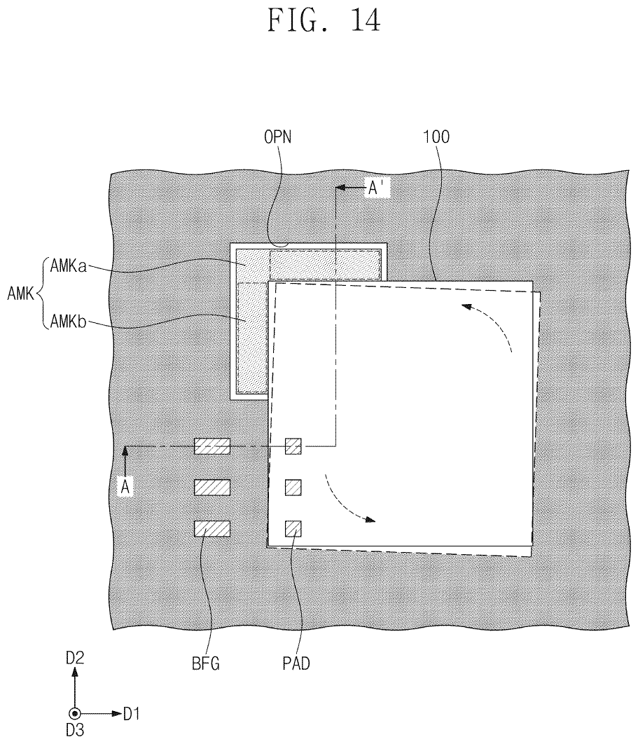

Referring to FIGS. 14, 15, and 16, the semiconductor chip 100 may be mounted on the base layer BS. Mounting the semiconductor chip 100 may include combining the first solder paste SP1 with the second solder paste SP2, moving the semiconductor chip 100 to approach the alignment mark AMK, and attaching the adhesive layer ADL on the lower surface 100b of the semiconductor chip 100 to the solder resist pattern SR.

The combining of the first solder paste SP1 with the second solder paste SP2 may be performed by a reflow process. The reflow process may cause the first solder paste SP1 and the second solder paste SP2 to melt and become liquid. As a result, an intermolecular force may occur between the first and second solder pastes SP1 and SP2 in a liquid state. Due to the intermolecular force between the first and second solder pastes SP1 and SP2, the first and second solder pastes SP1 and SP2 may come close to each other and be combined with each other. As a result, the first and second solder pastes SP1 and SP2 may be combined with each other to form one solder paste pattern SP. That is, the solder paste pattern SP may be composed of the first solder paste SP1 and the second solder paste SP2 on the first solder paste SP1. As the first and second solder pastes SP1 and SP2 contain substantially the same (and/or substantially similar) material, an interface between the first and second solder pastes SP1 and SP2 may not be distinguished. In at least some examples, the reflow process may be performed at about 120° C. to about 250° C.

In addition, surface tension may be generated in the solder paste pattern SP composed of the first and second solder pastes SP1 and SP2 in a liquid state. As a result, the solder paste pattern SP may fill a space between one side AMKs of the alignment mark AMK adjacent to the semiconductor chip 100 and the solder resist pattern SR in the opening region OPN of the solder resist pattern SR. Therefore, the solder paste pattern SP may not cover the upper surface AMKt of the alignment mark AMK.

The semiconductor chip 100 may move due to the intermolecular attraction between the first and second solder pastes SP1 and SP2 in a liquid state. In detail, the second solder paste SP2 in a liquid state may come closer to the first solder paste SP1 due to the intermolecular attraction between the first and second solder pastes SP1 and SP2. For example, the second solder paste SP2 may be brought closer to the first solder paste SP1 until the second solder paste SP2 vertically overlaps the first solder paste SP1. The semiconductor chip 100 may move due to the second solder paste SP2. The semiconductor chip 100 may rotate (e.g., move clockwise or counterclockwise) and/or move horizontally (e.g., laterally in the first direction D1 and/or the second direction D2). As a result, the semiconductor chip 100 may be brought closer to the alignment mark AMK. In addition, a horizontal distance HL between one side 100s of the semiconductor chip 100 adjacent to the alignment mark AMK and one side AMKs of the alignment mark AMK adjacent to the semiconductor chip 100 may be constant. As a result, the semiconductor chip 100 may be self-aligned to the alignment mark AMK. For example, the horizontal distance HL between the one side 100s of the semiconductor chip 100 and the one side AMKs of the alignment mark AMK may be about 30 μm or less.

As the second solder paste SP2 supporting the semiconductor chip 100 on the solder resist pattern SR is melted, the semiconductor chip 100 and the solder resist pattern SR may come closer. As a result, the adhesive layer ADL on the lower surface 100b of the semiconductor chip 100 and the solder resist pattern SR may come into contact with each other. Accordingly, the semiconductor chip 100 may be attached to the solder resist pattern SR when the semiconductor chip 100 is aligned to the alignment mark AMK.

Referring again to FIGS. 1, 2, and 3, the solder paste pattern SP may be solidified, and bonding wires WR may be formed on pads PAD of the semiconductor chip 100. Each of the bonding wires WR may be connected to connection pads BFG on the base layer BS. Forming the bonding wires WR may include bonding one end of the bonding wires WR to the pads PAD and bonding the other end of the bonding wires WR to the connection pads BFG.

Thereafter, a molding layer MOL covering the semiconductor chip 100 may be formed on the base layer BS. The molding layer MOL may cover the semiconductor chip 100, the alignment mark AMK, the bonding wires WR, the connection pads BFG, and the solder resist pattern SR that are exposed to the outside. After the molding layer MOL is formed, terminals SB may be formed on the lower surface of the base layer BS. As a result, a package substrate PSUB may be formed.

The method of manufacturing a semiconductor package according to embodiments of the inventive concepts may move the semiconductor chip 100 by using the intermolecular attraction between the first and second solder pastes SP1 and SP2 in a liquid state. The semiconductor chip 100 may be self-aligned as the semiconductor chip 100 approaches the alignment mark AMK. As a result, the bonding wires WR may be accurately bonded to the pads PAD of the semiconductor chip 100. Therefore, defects in the semiconductor package may be minimized or prevented.

The semiconductor package according to at least one embodiment of the inventive concepts may include the solder paste pattern disposed between the alignment mark and the solder resist pattern and on the lower surface of the semiconductor chip. In the method of manufacturing the semiconductor package, the two solder pastes may be combined to form one solder paste pattern. In this case, the semiconductor chip may be brought closer to the alignment mark and self-aligned due to the intermolecular attraction between the solder pastes. As a result, the bonding wires may be accurately connected on the pads of the semiconductor chip. Accordingly, the defects in the semiconductor package may be minimized or prevented, and the electrical characteristics of the semiconductor package may be improved.

In addition, the adhesive layer on the lower surface of the semiconductor chip may have the relatively larger planar area than that of the solder paste pattern. Accordingly, the potential for the semiconductor chip to be peeled off from the package substrate due to the bleeding phenomenon of the solder paste pattern is reduced and/or minimized. Accordingly, the durability of the semiconductor package may be improved.

While embodiments are described above, a person skilled in the art may understand that many modifications and variations are made without departing from the spirit and scope of the inventive concepts defined in the following claims. Accordingly, the example embodiments of the inventive concepts should be considered in all respects as illustrative and not restrictive, with the spirit and scope of the inventive concepts being indicated by the appended claims.

What is claimed is:

1. A semiconductor package comprising:
a package substrate;
a semiconductor chip on the package substrate;
a solder resist pattern between the package substrate and the semiconductor chip, the solder resist pattern defining an opening region;
an alignment mark on the package substrate and in the opening region; and
a solder paste pattern between the semiconductor chip and the package substrate and on a side surface of the alignment mark, the side surface adjacent to the semiconductor chip.

2. The semiconductor package of claim 1, wherein the solder paste pattern is in the opening region.

3. The semiconductor package of claim 1, wherein a lower surface of the semiconductor chip is higher than an upper surface of the alignment mark.

4. The semiconductor package of claim 1, wherein the semiconductor chip and the alignment mark do not overlap each other when viewed in a plan view.

5. The semiconductor package of claim 1, wherein the solder resist pattern and the alignment mark are horizontally spaced apart.

6. The semiconductor package of claim 1, further comprising:
an adhesive layer on a lower surface of the semiconductor chip,
wherein the adhesive layer is between the solder resist pattern and the semiconductor chip.

7. The semiconductor package of claim 1, wherein the solder paste pattern is in contact with a lower surface of the semiconductor chip and an upper surface of the package substrate.

8. The semiconductor package of claim 1, wherein a distance between the side surface of the semiconductor chip adjacent to the alignment mark and the side surface of the alignment mark adjacent to the semiconductor chip is 30 micrometers (μm) or less.

9. The semiconductor package of claim 1, wherein the alignment mark includes a first portion and at least one second portion extending from the first portion in a direction parallel to a side surface of the semiconductor chip.

10. The semiconductor package of claim 9, wherein the semiconductor chip is included in a plurality of semiconductor chips,
wherein the at least one second portion of the alignment mark includes a plurality of second portions, and
wherein each of the plurality of second portions is between adjacent semiconductor chips of the plurality of semiconductor chips when in viewed in a plan view.

11. A semiconductor package comprising:
a package substrate;
a first semiconductor chip on the package substrate;
a plurality of second semiconductor chips stacked on the first semiconductor chip;
a solder resist pattern between the package substrate and the first semiconductor chip, the solder resist pattern defining an opening region adjacent to the first semiconductor chip;
an adhesive layer between the first semiconductor chip and the solder resist pattern;
an alignment mark in the opening region; and
a solder paste pattern between the alignment mark and the solder resist pattern in the opening region such that at least a portion of the solder paste pattern vertically overlaps the first semiconductor chip.

12. The semiconductor package of claim 11, wherein a size of the adhesive layer is larger than a size of the solder paste pattern when viewed in a plan view.

13. The semiconductor package of claim 11, wherein the alignment mark includes a first portion and second portions extending from the first portion in directions parallel to side surfaces of the first semiconductor chip.

14. The semiconductor package of claim 11, wherein a lower surface of the first semiconductor chip is higher than an upper surface of the alignment mark, and
wherein the alignment mark and the solder resist pattern are spaced apart from each other.

15. The semiconductor package of claim 11, wherein the first semiconductor chip includes a volatile memory device, and
wherein each of the plurality of second semiconductor chips includes a nonvolatile memory device.

16. A method of manufacturing a semiconductor package, the method comprising:
forming a solder resist pattern on a base layer such that the solder resist pattern defines an opening region and includes an alignment mark in the opening;
depositing a first solder paste in the opening region;
forming an adhesive layer and a second solder paste on a lower surface of a semiconductor chip;
arranging the semiconductor chip on the base layer; and
mounting the semiconductor chip on the base layer,
wherein the mounting of the semiconductor chip includes forming a solder paste pattern by combining the first solder paste and the second solder paste to.

17. The method of claim 16, wherein a thickness of the first solder paste is 0.3 to 0.7 of a thickness of the solder resist pattern.

18. The method of claim 16, wherein the arranging of the semiconductor chip includes spacing the adhesive layer and the solder resist pattern apart from each other.

19. The method of claim 16, wherein the mounting of the semiconductor chip includes contacting the adhesive layer to the solder resist pattern.

20. The method of claim 16, wherein the forming the solder paste pattern includes the semiconductor chip self-aligning to the alignment mark due to intermolecular attraction between the first solder paste and the second solder paste.
